(19) United States
(12) Patent Application Publication
(10) Pub. No.: US 2019/0333743 A1
(43) Pub. Date: Oct. 31, 2019

(54) GAS SPRAYER FOR SUBSTRATE TREATMENT DEVICE, AND SUBSTRATE

(71) Applicant: JUSUNG ENGINEERING CO., LTD., Gwangju-si, Gyeonggi-do (KR)

(72) Inventors: Ho Bin YOON, Gwangju-si, Gyeonggi-do (KR); Seung Chul SHIN, Gwangju-si, Gyeonggi-do (KR); Jin Hyuk YOO, Gwangju-si, Gyeonggi-do (KR); Byoung Ha CHO, Gwangju-si, Gyeonggi-do (KR)

(21) Appl. No.: 16/310,414

(22) PCT Filed: Jul. 14, 2017
(86) PCT No.: PCT/KR2017/007564

§ 371 Date: Dec. 14, 2018

(30) Foreign Application Priority Data
Jul. 19, 2016 (KR) 10-2016-0091082
Jul. 13, 2017 (KR) 10-2017-0089261

(51) Int. Cl. H01J 37/32; H01L 21/687; C23C 16/50; C23C 16/458

(52) U.S. Cl. CPC H01J 37/32651; H01J 37/32715; H01J 37/32467; H01J 37/3244; H01J 2237/0262; H01L 21/68771; C23C 16/50; C23C 16/4584; H01J 2237/3321; H01L 21/68764

(57) ABSTRACT

The present inventive concept relates to a substrate processing apparatus and a gas distribution apparatus for substrate processing apparatuses including: a plasma generator generating plasma for performing a processing process on a substrate supported by a substrate supporting unit; a ground body coupled to the plasma generator; and a plasma shield shielding the plasma generated by the plasma generator, wherein the plasma generator includes a first electrode for generating the plasma and a second electrode coupled to the ground body at a position spaced apart from the first electrode so that a gas distribution space for distributing a process gas is provided between the first electrode and the second electrode, and the plasma shield shields the plasma, generated by the plasma generator, in at least one of a top of the substrate and a bottom of the substrate.

### TECHNICAL FIELD

The present inventive concept relates to a gas distribution apparatus for substrate processing apparatuses and a substrate processing apparatus, which perform a substrate processing process such as a deposition process of depositing a thin film on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a semiconductor manufacturing process is performed, and examples of the semiconductor manufacturing process include a thin film deposition process of depositing a thin film including a specific material on a substrate, a photo process of selectively exposing a portion of a thin film by using a photosensitive material, an etching process of removing a thin film corresponding to the selectively exposed portion to form a pattern, etc.

The semiconductor manufacturing process is performed inside a substrate processing apparatus which is designed based on an optimal environment for a corresponding process, and recently, substrate processing apparatuses for performing a deposition process or an etching process by using plasma are much used.

Examples of the substrate processing apparatuses based on plasma include plasma enhanced chemical vapor deposition (PECVD) apparatuses for forming a thin film by using plasma, plasma etching apparatuses for etching and patterning a thin film, etc.

FIG. 1 is a conceptual side view of a related art gas distribution apparatus.

Referring to FIG. 1, a related art gas distribution apparatus 100 includes a first electrode 110, a ground body 120, and a second electrode 130.

The first electrode 110 generates plasma for substrate processing. The first electrode 110 is coupled to the ground body 120. The second electrode 130 is coupled to the ground body 120. The first electrode is disposed inside the second electrode 130. The second electrode 130 is provided to surround an outer side of the first electrode 110, and the first electrode 110 is accommodated into an inner portion. The second electrode 130 is electrically grounded.

Therefore, when a plasma power is applied to the first electrode 110, plasma may be generated in a plasma area PA by an electric field generated between the first electrode 110 and the second electrode 130.

Here, in the related art gas distribution apparatus 100, the second electrode 130 is disposed on each of an inner side and an outer side of the first electrode 110, and thus, the plasma area PA extends to each of the inner side of the first electrode 110 and the outer side of the first electrode 110. Therefore, the related art gas distribution apparatus 100 has the following problems.

First, in the related art gas distribution apparatus 100, since the plasma area PA extends to the inner side of the first electrode 110 and the outer side of the first electrode 110, there is a problem where a density of the plasma generated in the plasma area PA is reduced.

Second, in the related art gas distribution apparatus 100, since the density of the plasma is reduced, a flow rate of a non-reaction process gas increases, and for this reason, there is a problem where a consumption amount of a process gas increases. Also, in the related art gas distribution apparatus 100, since the flow rate of the non-reaction process gas increases, the number of occurring particles increases, and for this reason, there is a problem where the quality of a substrate is reduced.

### DISCLOSURE

### Technical Problem

The present inventive concept is devised to solve the above-described problems and is for providing a gas distribution apparatus for substrate processing apparatuses and a substrate processing apparatus, which can decrease the incidence of the reduction in density of plasma generated in a plasma area despite the enlargement of the plasma area.

The present inventive concept is for providing a gas distribution apparatus for substrate processing apparatuses and a substrate processing apparatus, which can prevent a consumption amount of a process gas from increasing due to the occurrence of a non-reaction process gas and can prevent the quality of a substrate from being degraded due to an increase in the amount of occurring particles caused by the non-reaction process gas.

### Technical Solution

To solve the above-described problems, the present inventive concept may include the following elements.

A substrate processing apparatus according to the present inventive concept may include: a process chamber; a substrate supporting unit installed in the process chamber to support a plurality of substrates, the substrate supporting unit rotating about a rotational shaft; a chamber lid covering an upper portion of the process chamber; a plasma generator generating plasma toward the substrate supporting unit; and a plasma shield shielding the plasma, generated by the plasma generator, in at least one of a top of the substrate and a bottom of the substrate.

A gas distribution apparatus for substrate processing apparatuses according to the present inventive concept may include: a plasma generator generating plasma for performing a processing process on a substrate supported by a substrate supporting unit; a ground body coupled to the plasma generator; and a plasma shield shielding the plasma generated by the plasma generator, wherein the plasma generator may include a first electrode for generating the plasma and a second electrode coupled to the ground body at a position spaced apart from the first electrode so that a gas distribution space for distributing a process gas is provided between the first electrode and the second electrode, and the plasma shield may shield the plasma, generated by the plasma generator, in at least one of a top of the substrate and a bottom of the substrate.

### Advantageous Effects

According to the present inventive concept, the following effects can be obtained.

Since the present inventive concept is implemented to decrease a degree to which a plasma area where plasma is generated is enlarged toward a rotational shaft of a substrate supporting unit, high-density plasma may be generated in the plasma area, and thus, in performing a processing process on a substrate, an efficiency of a chemical reaction increases, thereby increasing an efficiency of the processing process.

The present inventive concept decreases a non-reaction process gas to reduce a consumption amount of a process gas, and thus, can decrease the process cost of a processing process and reduce the amount of particles occurring due to the non-reaction process gas, thereby enhancing the quality of a substrate for which the processing process is completed.

### DESCRIPTION OF DRAWINGS

FIG. 1 is a conceptual side view of a related art gas distribution apparatus.

FIG. 2 is a schematically exploded perspective view of a substrate processing apparatus according to the present inventive concept.

FIG. 3 is a schematic bottom view of a gas distribution apparatus in a substrate processing apparatus according to the present inventive concept.

FIG. 4 is a schematic front cross-sectional view illustrating a gas distribution apparatus in a substrate processing apparatus according to the present inventive concept with respect to line I-I of FIG. 3.

FIG. 5 is a schematic side cross-sectional view illustrating a gas distribution apparatus in a substrate processing apparatus according to the present inventive concept with respect to line II-II of FIG. 3.

FIG. 6 is a schematic plan cross-sectional view of a substrate processing apparatus according to the present inventive concept.

FIG. 7 is a schematic perspective view of a substrate processing apparatus according to the present inventive concept.

FIG. 8 is a schematic front cross-sectional view illustrating a source gas distribution unit in a substrate processing apparatus according to the present inventive concept with respect to line I-I of FIG. 3.

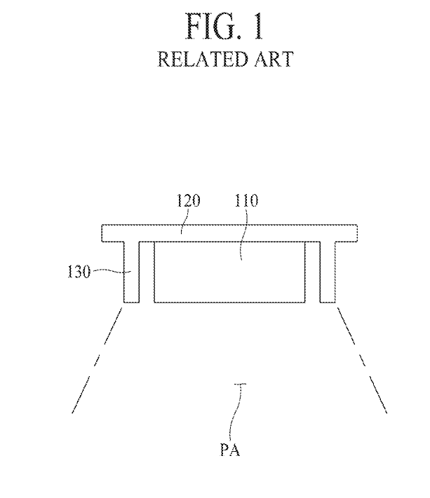

### DETAILED DESCRIPTION

Hereinafter, embodiments of a substrate processing apparatus according to the present inventive concept will be described in detail with reference to the accompanying drawings. A gas distribution apparatus for substrate processing apparatuses according to the present inventive concept may be included in a substrate processing apparatus according to the present inventive concept, and thus, will be described together while describing embodiments of the substrate processing apparatus according to the present inventive concept.

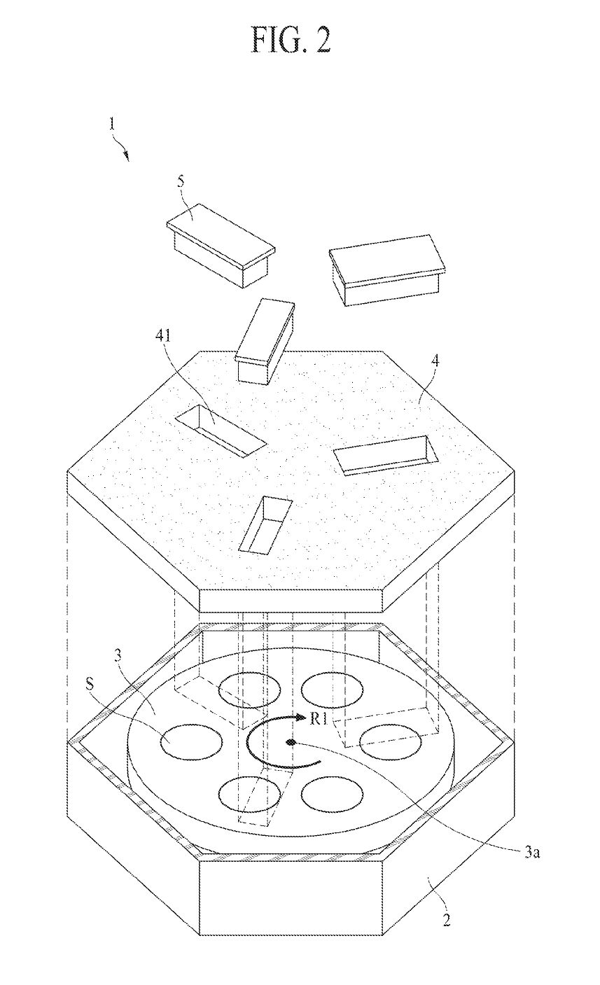

Referring to FIG. 2, a substrate processing apparatus 1 according to the present inventive concept performs a processing process on a substrate S. For example, the substrate processing apparatus 1 according to the present inventive concept may perform a deposition process of depositing a thin film on the substrate S. The substrate processing apparatus 1 according to the present inventive concept includes a process chamber 2 where the deposition process is performed, a substrate supporting unit 3 installed in the process chamber 2, a chamber lid 4 that covers an upper portion of the process chamber 2, and a gas distribution apparatus 5 that distributes a process gas.

Referring to FIG. 2, the process chamber 2 provides a process space where the processing process is performed. The substrate supporting unit 3 and the chamber lid 4 may be installed in the process chamber 2. An exhaust unit for exhausting a gas and/or the like remaining in the process space may be installed in the process chamber 2.

Referring to FIG. 2, the substrate supporting unit 3 supports a plurality of substrates S. The substrates S are loaded into the process chamber 2 by a loading apparatus (not shown) installed outside the process chamber 2. The substrates S may be semiconductor substrates or wafers. The substrate S for which the processing process is completed may be unloaded from the process chamber 2 an unloading apparatus (not shown) installed outside the process chamber 2. The unloading apparatus and the loading apparatus may be implemented as one piece of equipment.

The substrate supporting unit 3 may be installed in the process chamber 2 so as to be located inside the process chamber 2. The substrate supporting unit 3 may be rotatably installed in the process chamber 2. The substrate supporting unit 3 may be installed in the process chamber 2 so as to clockwise and counterclockwise rotate about a rotational shaft 3a. In this case, the substrates S may be supported by the substrate supporting unit 3 so as to be spaced apart from each other and arranged at the same angle along a rotational direction (hereinafter referred to as ‘a first rotational direction (an R1 arrow direction)’) of the substrate supporting unit 3. In FIG. 2, it is illustrated that the first rotational direction (the R1 arrow direction) is a clockwise direction about the rotational shaft 3a, but the first rotational direction (the R1 arrow direction) may be a counterclockwise direction about the rotational shaft 3a without being limited thereto. The substrate supporting unit 3 may rotate in the first rotational direction (the R1 arrow direction) by a driver (not shown). The driver may include a motor that generates a rotational force for rotating the substrate supporting unit 3. The driver may further include a power transfer unit (not shown) that connects the motor and the substrate supporting unit 3. The power transfer unit may be a pulley, a belt, a chain, a gear, or the like. The driver may be coupled to the process chamber 2 so as to be located outside the process chamber 2.

Referring to FIG. 2, the chamber lid 4 is coupled to the process chamber 2 to cover the upper portion of the process chamber 2. Therefore, the chamber lid 4 may seal the process space. The chamber lid 4 and the process chamber 2, as illustrated in FIG. 2, may be provided in a hexagonal structure, but may be provided in a cylindrical structure, an elliptical structure, a polygonal structure, or the like without being limited thereto.

Referring to FIG. 2, the gas distribution apparatus 5 distributes a process gas toward the substrate supporting unit 3. The gas distribution apparatus 5 is installed in the chamber lid 4. The gas distribution apparatus 5 may be coupled to the chamber lid 4 so as to be located over the substrate supporting unit 3. An installation hole 41 where the gas distribution apparatus 5 is installed may be provided in the chamber lid 4. The gas distribution apparatus 5 may be inserted into the installation hole 41 and may be installed in the chamber lid 4. The installation hole 41 may be provided to pass through the chamber lid 4.

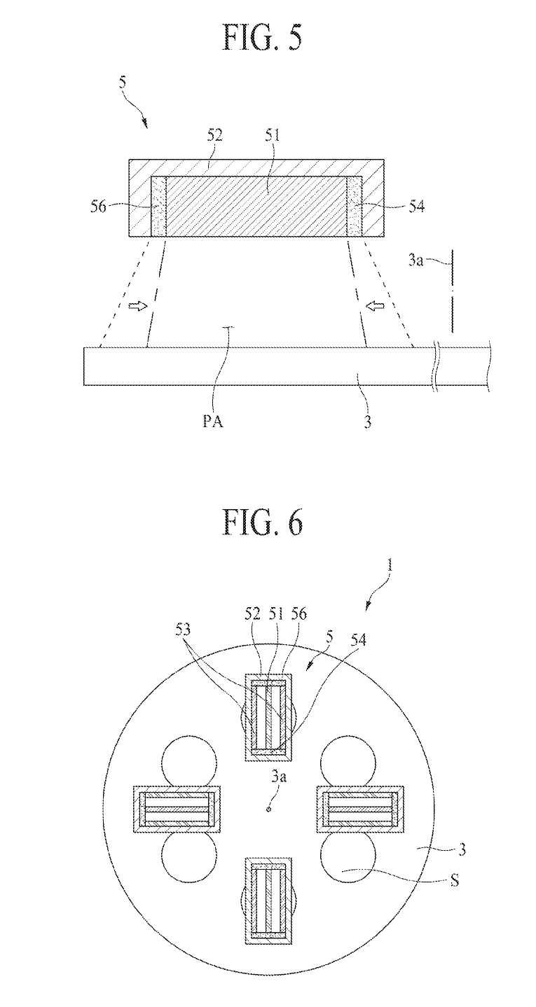

Here, the substrate processing apparatus 1 according to the present inventive concept may include a plurality of the gas distribution apparatuses 5. At least some of the gas distribution apparatuses 5 may be implemented to activate the process gas by using plasma, and distribute the activated process gas. At least some of the gas distribution apparatuses 5 may be implemented to distribute the process gas without using the plasma. The gas distribution apparatus 5 that activates the process gas by using plasma and distributes the activated process gas will be described below in detail with reference to FIGS. 2 to 5.

The gas distribution apparatus 5 may include a plasma generator.

The plasma generator generates plasma toward the substrate supporting unit 3. The plasma generator may activate the process gas to generate the plasma. To this end, the plasma generator may generate an electric field generating the plasma by using a plurality of electrodes. The plasma generator may be disposed in the gas distribution apparatus 5 to face the substrate S.

The plasma generator may include a first electrode 51 and a second electrode 53.

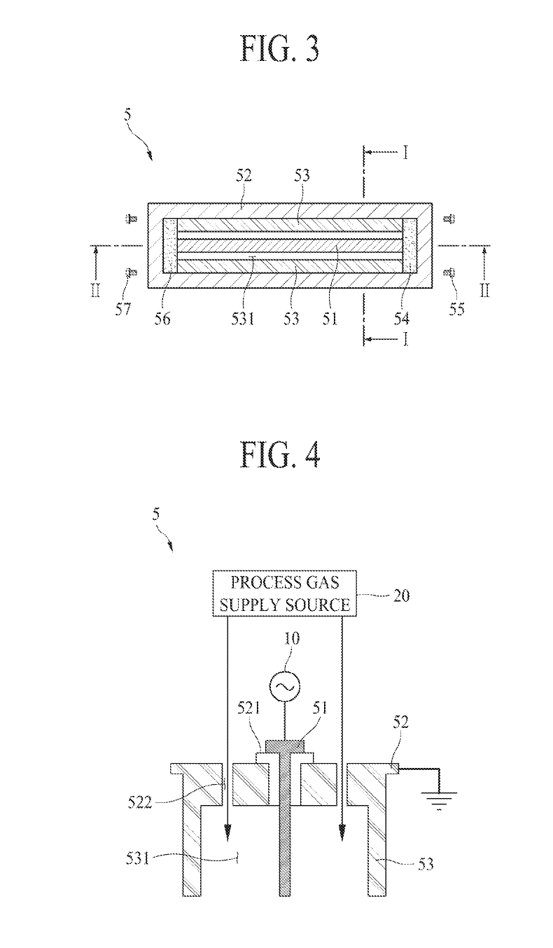

The first electrode 51 is used to generate the plasma. The substrate S supported by the substrate supporting unit 3 passes by a lower side of the first electrode 51 while rotating about the rotational shaft 3a. The first electrode 51 may generate the plasma by using a plasma power applied from a plasma power supply source 10 (shown in FIG. 4). That is, the first electrode 51 may be implemented with a plasma electrode to which the plasma power is applied. In this case, the plasma may be generated from an electric field generated between the first electrode 51 and the second electrode 53, based on the plasma power. Therefore, the process gas may be activated by the plasma and distributed. The plasma power supply source 10 may apply the plasma power based on a radio frequency (RF) power to the first electrode 51. In a case where the plasma power supply source 10 applies the plasma power based on the RF power, the plasma power supply source 10 may apply the plasma power based on a low frequency (LF) power, a middle frequency (MF) power, a high frequency (HF) power, or a very high frequency (VHF) power. The LF power may have a frequency within a range of 3 kHz to 300 kHz. The MF power may have a frequency within a range of 300 kHz to 3 MHz. The HF power may have a frequency within a range of 3 MHz to 30 MHz. The VHF power may have a frequency within a range of 30 MHz to 300 MHz.

The first electrode 51 may be coupled to the second electrode 53. The first electrode 51 may be coupled to the ground body 52, and thus, may be coupled to the second electrode 53. The ground body 52 may be coupled to the chamber lid 4. The ground body 52 may be electrically connected to the chamber lid 4, and thus, may be electrically grounded through the chamber lid 4. The ground body 52 may be inserted into the installation hole 41, and thus, may be coupled to the chamber lid 4.

The first electrode 51 may be coupled to the ground body 52 so as to be located between the second electrodes 53. The first electrode 51 may be located between the second electrodes 53 along the first rotational direction (the R1 arrow direction). The first electrode 51 may be inserted into and coupled to the ground body 52 in order for a portion of the first electrode 51 to be located between the second electrodes 53. In this case, the portion of the first electrode 51 located between the second electrodes 53 may be disposed in parallel with the second electrode 53.

An insulation member 521 (shown in FIG. 4) may be located between the first electrode 51 and the ground body 52. The insulation member 521 may electrically insulate the first electrode 51 from the ground body 52. The insulation member 521 may be inserted into the ground body 52, and thus, may be coupled to the ground body 52. The first electrode 51 may be inserted into a through hole which is provided in the insulation member 521, and thus, may be coupled to the ground body 52 through the insulation member 521.

The first electrode 51 may be coupled to the second electrode 53. In this case, the first electrode 51 may be coupled to the ground body 52, and thus, may be coupled to the second electrode 53. The second electrode 53 may be coupled to the ground body 52 to protrude in a direction from the ground body 52 to the substrate supporting unit 3. The second electrode 53 may be coupled to the ground body 52 so as to be located on both sides of the first electrode 51. In this case, the second electrode 53 may be located on both sides of the first electrode 51 along the first rotational direction (the R1 arrow direction). When the plasma power is applied to the first electrode 51, the plasma may be generated from the electric field generated between the second electrode 53 and the first electrode 51. In this case, the second electrode 53 may be implemented as a ground electrode for grounding in an operation of generating the plasma. The second electrode 53 and the ground body 52 may be provided as one body.

A gas distribution space 531 may be provided in the second electrode 53. The process gas may be distributed through the gas distribution space 531. The gas distribution space 531 may be located inside the second electrode 53. One side of the second electrode 53 may be opened through the gas distribution space 531. The second electrode 53 may be installed in order for the opened one side to face the substrate supporting unit 3. A portion of the first electrode 51 may be inserted into and coupled to the ground body 52 so as to be located in the gas distribution space 531. In this case, the gas distribution space 531 may be located between the first electrode 51 and the ground body 52. The second electrode 53 may be coupled to the ground body 52 at a position spaced apart from the first electrode 51 in order for the gas distribution space 531 to be provided between the second electrode 53 and the first electrode 51.

The gas distribution space 531 may be connected to a gas supply hole 522 which is provided in the ground body 52, so as to enable communication therebetween. The gas supply hole 522 is provided to pass through the ground body 52. The gas supply hole 522 may be connected to a process gas supply source 20. Therefore, the process gas supplied from the process gas supply source 20 may be supplied to the gas distribution space 531 through the gas supply hole 522, and then, may be distributed toward the substrate supporting unit 3 through the gas distribution space 531. The gas supply hole 522 may be provided in plurality in the ground body 52. In this case, the gas supply holes 522 may be located on both sides of the first electrode 51. When the insulation member 521 is coupled to the ground body 52, the insulation member 521 may be coupled to the ground body 52 so as to be located between the gas supply holes 522.

The gas distribution apparatus 5 may include a plasma shield.

The plasma shield is located on at least one of a top of the substrate S and a bottom of the substrate S. The top of the substrate S is a side which faces the rotational shaft 3a of the substrate supporting unit 3 with respect to the substrate S. The bottom of the substrate S is a side opposite to the top of the substrate S with respect to the substrate S. That is, the top may denote a direction facing a center portion of the process chamber 2, and the bottom may denote a direction facing an edge portion of the process chamber 2. With respect to the substrate S, a portion of the substrate S facing the center portion of the process chamber 2 corresponds to the top of the substrate S, and a portion of the substrate S facing the edge portion of the process chamber 2 corresponds to the bottom of the substrate S.

The plasma shield may be located on the top of the substrate S, and thus, may shield some of plasma generated from the top of the substrate S. The plasma shield may be located on the bottom of the substrate S, and thus, may shield some of plasma generated from the bottom of the substrate S. The plasma shield may be located on the top of the substrate S and the bottom of the substrate S, namely, both sides, and thus, may shield some of plasma generated from the both sides of the substrate S.

Therefore, the substrate processing apparatus 1 according to the present inventive concept may shield at least one of the top of the substrate S and the bottom of the substrate S by using the plasma shield, thereby decreasing a degree to which the plasma area PA is enlarged to at least one of the top of the substrate S and the bottom of the substrate S. The plasma area PA denotes an area where plasma is generated. Therefore, the substrate processing apparatus 1 according to the present inventive concept may be implemented in order for the plasma area PA to concentrate on a lower side of the plasma generator, and thus, may generate high-density plasma, thereby increasing an efficiency of a chemical reaction on the substrate S. Therefore, the substrate processing apparatus 1 according to the present inventive concept can further increase an efficiency of the processing process, and moreover, may decrease a non-reaction process gas to reduce a consumption amount of the process gas, thereby decreasing the process cost of the processing process. The substrate processing apparatus 1 according to the present inventive concept can further reduce the amount of particles occurring due to the non-reaction process gas, thereby enhancing the quality of the substrate S for which the processing process is completed.

The plasma shield and the second electrode 53 may be formed of different materials. Therefore, the plasma shield may be differentiated from the second electrode 53 and may be effectively shield at least one of the top of the substrate S and the bottom of the substrate S. The plasma shield may be formed of a nonconductor or an insulator. Therefore, when the plasma power is applied to the first electrode 51, an electric field is not generated between the plasma shield and the first electrode 51. Accordingly, the substrate processing apparatus 1 according to the present inventive concept can decrease a degree to which the plasma area PA is enlarged to at least one of the top of the substrate S and the bottom of the substrate S. In this case, the second electrode 53 may be formed of a conductor. For example, the second electrode 53 may be formed of aluminum. The plasma shield may be formed of ceramic.

The plasma shield may be located between the ground body 52 and the plasma generator. Therefore, by using the plasma shield, the substrate processing apparatus 1 according to the present inventive concept prevents an electric field from being generated between the plasma generator and the ground body 52. Therefore, the substrate processing apparatus according to the present inventive concept can further decrease a degree to which the plasma area PA is enlarged by the plasma generator and the ground body 52 located on at least one of the top of the substrate S and the bottom of the substrate S.

The plasma shield may be disposed not to cover a lower side of the gas distribution space 531. For example, the plasma shield may be disposed not to cover the first electrode 51 and a lower side of the second electrode 52, and thus, may not cover the lower side of the gas distribution space 531. To this end, the plasma shield may be disposed on at least one of the top facing the rotational shaft 3a of the substrate supporting unit 3 and the bottom opposite to the top with respect to the gas distribution space 531.

Therefore, in comparison with a comparative example where the plasma shield is provided to cover a portion of the lower side of the gas distribution space 531 for Shielding plasma, the substrate processing apparatus 1 according to the present inventive concept can prevent the process gas from being shielded and accumulated by the plasma shield in an operation of distributing the process gas toward the substrate S. Therefore, the substrate processing apparatus 1 according to the present inventive concept decreases the process gas which is consumed by the plasma shield without being distributed toward the substrate S, thereby more reducing a consumption amount of the process gas and moreover more decreasing the amount of particles occurring due to the non-reaction process gas.

The plasma shield may include a first Shielding member 54.

The first Shielding member 54 is located between the rotational shaft 3a of the substrate supporting unit 3 and the first electrode 51 so as to be located on the top of the substrate S. The first Shielding member 54 may be formed of a material different from that of the second electrode 53. Therefore, the first Shielding member 54 may shield a space between the first electrode 51 and the rotational shaft 3a of the substrate supporting unit 3. Accordingly, the substrate processing apparatus 1 according to the present inventive concept can obtain the following effects.

First, by using the first Shielding member 54, the substrate processing apparatus 1 according to the present inventive concept decreases a degree to which the plasma area PA is enlarged to the top of the substrate S, and thus, the plasma area PA concentrates on the lower side of the first electrode 51. Therefore, in the substrate processing apparatus 1 according to the present inventive concept, high-density plasma may be generated in the plasma area PA, and thus, in performing the processing process on the substrate S, an efficiency of a chemical reaction increases, thereby increasing an efficiency of the processing process.

Second, the substrate processing apparatus 1 according to the present inventive concept generates high-density plasma by using the first Shielding member 54, thereby reducing the non-reaction process gas. Therefore, the substrate processing apparatus 1 according to the present inventive concept decreases a consumption amount of the process gas, thereby reducing the process cost of the processing process. Also, the substrate processing apparatus 1 according to the present inventive concept can reduce the amount of particles occurring due to the non-reaction process gas, thereby enhancing the quality of the substrate S for which the processing process is completed.

The first Shielding member 54 may be formed of a nonconductor or an insulator. Therefore, when the plasma power is applied to the first electrode 51, an electric field is not generated between the first Shielding member 54 and the first electrode 51. Accordingly, the substrate processing apparatus 1 according to the present inventive concept can decrease a degree to which the plasma area PA is enlarged to the rotational shaft 3a of the substrate supporting unit 3 between the first electrode 51 and the rotational shaft 3a of the substrate supporting unit 3. In this case, the second electrode 53 may be formed of a conductor. For example, the second electrode 53 may be formed of aluminum. The first Shielding member 54 may be formed of ceramic.

The first Shielding member 54 may be coupled to the second electrode 53 to contact the first electrode 51. Therefore, a portion of the gas distribution space 531 located between the first Shielding member 54 and the first electrode 51 is plugged by the first Shielding member 54 and the first electrode 51. Therefore, the substrate processing apparatus 1 according to the present inventive concept decreases a flow rate of a process gas distributed to a space between the first Shielding member 54 and the first electrode 51, thereby reducing the incidence that a process gas distributed to the plasma area PA is mixed with a process gas in another area. Accordingly, the substrate processing apparatus 1 according to the present inventive concept can prevent the occurrence of an abnormal phenomenon where normal ignition is not performed or arching occurs in generating plasma, and moreover, can generate high-density plasma in the plasma area PA.

The first Shielding member 54 may be coupled to the second electrode 53 to contact the second electrode 53 located on the both sides of the first electrode 51 in the first rotational direction (the R1 arrow direction). The first Shielding member 54 may be provided to have a length corresponding to a length obtained by summating the second electrode 53, the first electrode 51, and the gas distribution space 531 located between the first electrode 51 and the second electrode 53, with respect to the first rotational direction (the R1 arrow direction). The first Shielding member 54 may be coupled to the first electrode 51.

The plasma shield may include a first coupling member 55 (shown in FIG. 3).

The first coupling member 55 couples the first Shielding member 54 to the second electrode 53. The first coupling member 55 may be inserted into each of the first Shielding member 54 and the second electrode 53, and thus, may couple the first Shielding member 54 to the second electrode 53. The first coupling member 55 and the first Shielding member 54 may be formed of the same material. Accordingly, by using the first coupling member 55, the substrate processing apparatus 1 according to the present inventive concept may generate high-density plasma in the plasma area PA and may couple the first Shielding member 54 to the second electrode 53.

The first coupling member 55 and the first Shielding member 54 may each be formed of a nonconductor or an insulator. In this case, the second electrode 53 may be formed of a conductor. The first coupling member 55 and the first Shielding member 54 may each be formed of ceramic. The first coupling member 55 may be implemented in a bolt form where a screw thread is formed on an outer circumference. In this case, a first fastening hole where a screw thread corresponding to the screw thread formed in the first coupling member 55 is formed may be provided in the first Shielding member 54 and the second electrode 53.

The plasma shield may include a second Shielding member 56.

The second Shielding member 56 may be located at a position spaced apart from the first Shielding member 54 so as to be located on the bottom of the substrate S. The first electrode 51 may be located between the second Shielding member 56 and the first Shielding member 54. The second electrode 53 may be located between the second Shielding member 56 and the first Shielding member 54. In this case, the first Shielding member 54 may be located on an inner side of the first electrode 51 facing the rotational shaft 3a of the substrate supporting unit 3. The second Shielding member 54 may be located on an outer side of the first electrode 51. The second Shielding member 56 may be formed of a material different from that of the second electrode 53. Accordingly, the second Shielding member 56 may shield the outer side of the first electrode 51. The first Shielding member 54 may shield the inner side of the first electrode 51.

Therefore, the substrate processing apparatus 1 according to the present inventive concept may shield at least one of the inner side of the first electrode 51 and the outer side of the first electrode 51 by using the second Shielding member 56 and the first Shielding member 54, thereby decreasing a degree to which the plasma area PA is enlarged to the inner side of the first electrode 51 and the outer side of the first electrode 51. Therefore, the substrate processing apparatus 1 according to the present inventive concept may be implemented in order for the plasma area PA to concentrate on a lower side of the first electrode 51, and thus, may generate high-density plasma, thereby further increasing an efficiency of a chemical reaction on the substrate S. Therefore, the substrate processing apparatus 1 according to the present inventive concept can further increase an efficiency of the processing process, and moreover, may decrease a non-reaction process gas to reduce a consumption amount of the process gas, thereby further decreasing the process cost of the processing process. The substrate processing apparatus 1 according to the present inventive concept can further reduce the amount of particles occurring due to the non-reaction process gas, thereby enhancing the quality of the substrate S for which the processing process is completed.

The second Shielding member 56 may be formed of a nonconductor or an insulator. Therefore, when the plasma power is applied to the first electrode 51, an electric field is not generated between the second Shielding member 56 and the first electrode 51. Accordingly, the substrate processing apparatus 1 according to the present inventive concept can decrease a degree to which the plasma area PA is enlarged to the outer side of the first electrode 51. The second Shielding member 56 may be formed of ceramic. The second Shielding member 56 and the first Shielding member 54 may be formed of the same material.

The second Shielding member 56 may be coupled to the second electrode 53 to contact the first electrode 51. Therefore, a portion of the gas distribution space 531 located between the second Shielding member 56 and the first electrode 51 is plugged by the second Shielding member 56 and the first electrode 51. Therefore, the substrate processing apparatus 1 according to the present inventive concept decreases a flow rate of a process gas distributed to a space between the second Shielding member 56 and the first electrode 51, thereby reducing a degree to which a process gas distributed to the plasma area PA is mixed with a process gas in another area. Accordingly, the substrate processing apparatus 1 according to the present inventive concept can prevent the occurrence of an abnormal phenomenon where normal ignition is not performed or arching occurs in generating plasma, and moreover, can generate high-density plasma in the plasma area PA.

The second Shielding member 56 may be coupled to the second electrode 53 to contact the second electrode 53 located on the both sides of the first electrode 51 in the first rotational direction (the R1 arrow direction). The second Shielding member 56 may be provided to have a length corresponding to a length obtained by summating the second electrode 53, the first electrode 51, and the gas distribution space 531 located between the first electrode 51 and the second electrode 53, with respect to the first rotational direction (the R1 arrow direction). In this case, the second electrode 53, the gas distribution space 531, and the first electrode 51 may be located between the second shielding member 56 and the first shielding member 54. The gas distribution space 531 may be located inside the second shielding member 56, the first shielding member 54, and the second electrode 53. The second shielding member 56 may be coupled to the first electrode 51.

The plasma shield may include a second coupling member 57 (shown in FIG. 3).

The second coupling member 57 couples the second shielding member 56 to the second electrode 53. The second coupling member 57 may be inserted into each of the second shielding member 56 and the second electrode 53, and thus, may couple the second shielding member 56 to the second electrode 53. The second coupling member 57 and the second shielding member 56 may be formed of the same material. Accordingly, by using the second coupling member 57, the substrate processing apparatus 1 according to the present inventive concept may generate high-density plasma in the plasma area PA and may couple the second shielding member 56 to the second electrode 53.

The second coupling member 57 and the second shielding member 56 may each be formed of a nonconductor or an insulator. In this case, the second electrode 53 may be formed of a conductor. The second coupling member 57 and the second shielding member 56 may each be formed of ceramic. The second coupling member 57 may be implemented in a bolt form where a screw thread is formed on an outer circumference. In this case, a first fastening hole where a screw thread corresponding to the screw thread formed in the second coupling member 57 is formed may be provided in the second shielding member 56 and the second electrode 53.

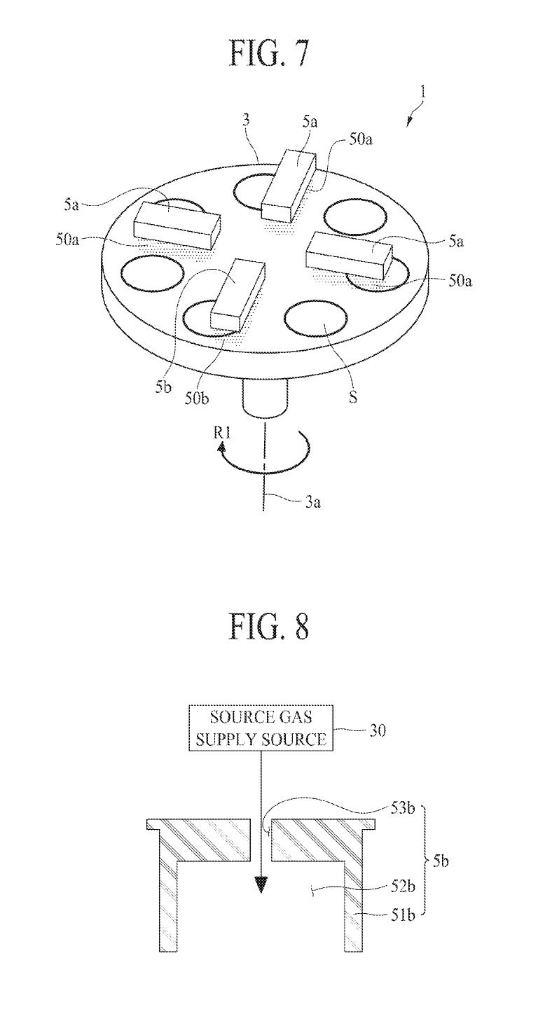

Referring to FIGS. 2 to 7, the substrate processing apparatus 1 according to the present inventive concept may include a reactant gas distribution unit 5a (shown in FIG. 7).

The reactant gas distribution unit 5a distributes a reactant gas. The reactant gas is included in the process gas used in the processing process. The reactant gas distribution unit 5a may be installed in the chamber lid 4 to distribute the reactant gas toward the substrate supporting unit 3. In this case, the reactant gas distribution unit 5a may be installed in the chamber lid 4 so as to be located over the substrate supporting unit 3. The reactant gas distribution unit 5a may be inserted into the installation hole 41 and may be installed in the chamber lid 4.

The reactant gas distribution unit 5a may activate the reactant gas by using plasma to distribute the activated reactant gas toward the substrate supporting unit 3. In this case, the reactant gas distribution unit 5a may include the first electrode 51, the ground body 52, the second electrode 53, and the plasma shield. The plasma shield may include the first shielding member 54. Alternatively, the plasma shield may include the first shielding member 54 and the second shielding member 56. Except that the process gas is changed to the reactant gas in the above-described gas distribution apparatus 5, the first electrode 51, the ground body 52, the second electrode 53, and the plasma shield are approximately the same, and thus, their detailed descriptions are omitted. The first coupling member 55 and the second coupling member 57 included in the plasma shield may be applied in implementing the reactant gas distribution unit 5a.

The reactant gas distribution unit 5a may distribute the reactant gas to a reactant gas distribution area 50a (shown in FIG. 7). In this case, the substrates S supported by the substrate supporting unit 3 may pass by the reactant gas distribution area 50a according to the substrate supporting unit 3 rotating in the first rotational direction (the R1 arrow direction). Therefore, the reactant gas distribution unit 5a may distribute the reactant gas to the substrate S located in the reactant gas distribution area 50a. The reactant gas distribution area 50a may be located between the reactant gas distribution unit 5a and the substrate supporting unit 3.

Referring to FIGS. 2 and 7, the substrate processing apparatus 1 according to the present inventive concept may include a source gas distribution unit 5b (shown in FIG. 7).

The source gas distribution unit 5b distributes a source gas. The source gas is included in the process gas used in the processing process. The source gas distribution unit 5b may be installed in the chamber lid 4 to distribute the source gas toward the substrate supporting unit 3. In this case, the source gas distribution unit 5b may be installed in the chamber lid 4 so as to be located over the substrate supporting unit 3. The source gas distribution unit 5b may be inserted into the installation hole 41 and may be installed in the chamber lid 4.

The source gas distribution unit 5b may distribute the source gas to a source gas distribution area 50b (shown in FIG. 7). In this case, the substrates S supported by the substrate supporting unit 3 may pass by the source gas distribution area 50b according to the substrate supporting unit 3 rotating in the first rotational direction (the R1 arrow direction). Therefore, the source gas distribution unit 5b may distribute the source gas to the substrate S located in the source gas distribution area 50b. The source gas distribution area 50b may be located between the source gas distribution unit 5b and the substrate supporting unit 3. In a case where the substrate processing apparatus 1 according to the present inventive concept performs a deposition process of depositing a thin film on the substrate S, the source gas distribution unit 5b may be implemented to distribute a source gas including a thin film material which is to be deposited on the substrate S.

Referring to FIGS. 2, 7, and 8, the source gas distribution unit 5b may include a source gas housing 51b (shown in FIG. 8), a source gas distribution space 52b (shown in FIG. 8), and a source gas supply hole 53b (shown in FIG. 8).

The source gas housing 51b may be installed in the chamber lid 4. The source gas housing 51b may be inserted into the installation hole 41 (shown in FIG. 2) provided in the chamber lid 4, and thus, may be installed in the chamber lid 4. In this case, a plurality of installation holes 41 may be provided in the chamber lid 4. The source gas housing 51b may be provided in a wholly rectangular parallelepiped shape, but may be provided in another shape, which enables the source gas housing installed in the chamber lid 4 to distribute the source gas, such as a cylindrical shape without being limited thereto.

The source gas distribution space 52b may be provided in the source gas housing 51b. The source gas distribution space 52b may be located inside the source gas housing 51b. One side of the source gas housing 51b may be opened through the source gas distribution space 52b. The source gas housing 51b may be installed in the chamber lid 4 in order for the opened one side to face the substrate supporting unit 3. The source gas may be distributed toward the substrate supporting unit 4 via the source gas distribution space 52b, and thus, may be distributed to the substrate S located in the source gas distribution area 50b.

The source gas supply hole 53b may be provided to pass through the source gas housing 51b. The source gas supply hole 53b may be provided in the source gas distribution space 52b so as to enable communication therebetween. The source gas supply hole 53b may be connected to a source gas supply source 30 that supplies the source gas. Therefore, the source gas supplied from the source gas supply source 30 may move to the source gas distribution space 52b through the source gas supply hole 53b, and then, may be distributed to the source gas distribution area 50b via the source gas distribution space 52b.

The source gas distribution unit 5b may be implemented to distribute the source gas to the source gas distribution unit 5b without using plasma. In this case, the source gas distribution unit 5b is implemented not to include the first electrode 51, the first shielding member 54, the first coupling member 55, the second shielding member 56, and the second coupling member 57.

The source gas distribution unit 5b and the reactant gas distribution unit 5a may be disposed at positions spaced apart from each other. The source gas distribution unit 5b and the reactant gas distribution unit 5a may be inserted into different installation holes 41 of the installation holes 41 provided in the chamber lid 4, and thus, may be installed in the chamber lid 4 at the positions spaced apart from each other. The reactant gas distribution unit 5a may be installed in the chamber lid 4 at a position spaced apart from the source gas distribution unit 5b along the first rotational direction (the R1 arrow direction). Therefore, the reactant gas distribution unit 5a may distribute the reactant gas to the substrate S located in the reactant gas distribution area 50a via the source gas distribution area 50b. In this case, the substrates S supported by the substrate supporting unit 3 may sequentially pass by the source gas distribution area 50b and the reactant gas distribution area 50a according to the substrate supporting unit 3 rotating in the first rotational direction (the R1 arrow direction), and thus, the processing process may be performed.

Therefore, the substrate processing apparatus 1 according to the present inventive concept may be implemented so that the processing processes is performed on individual substrates S in the source gas distribution area 50b and the reactant gas distribution area 50a. Accordingly, the substrate processing apparatus 1 according to the present inventive concept can increase a productivity of the substrate S for which the processing process is completed.

Referring to FIGS. 2 and 8, the substrate processing apparatus 1 according to the present inventive concept may include a first purge gas distribution unit and a second purge gas distribution unit.

The first purge gas distribution unit may be installed in the chamber lid 4. The first purge gas distribution unit may distribute a purge gas toward the substrate supporting unit 3. Therefore, the first purge gas distribution unit may implement a purge function, and moreover, may divide a space between the substrate supporting unit 3 and the chamber lid 4 into a plurality of areas along the first rotational direction (the R1 arrow direction). The first purge gas distribution unit may be installed in the chamber lid 4 so as to be located over the substrate supporting unit 3.

The first purge gas distribution unit may be installed in the chamber lid 4 at a position spaced apart from the source gas distribution unit 5b along the first rotational direction (the R1 arrow direction). Therefore, the first purge gas distribution unit may implement an air curtain between the source gas distribution area 50b and the reactant gas distribution area 50a, thereby spatially dividing the source gas distribution area 50b and the reactant gas distribution area 50a. Also, the first purge gas distribution unit may distribute the purge gas to the substrate S which has undergone the source gas distribution area 50b, thereby purging the source gas which remains without being deposited on the substrate S. The first purge gas distribution unit may distribute an inert gas toward the substrate supporting unit 3 as the purge gas. For example, the first purge gas distribution unit may distribute argon toward the substrate supporting unit 3 as the purge gas.

The second purge gas distribution unit may be installed in the chamber lid 4. The second purge gas distribution unit may distribute the purge gas toward the substrate supporting unit 3. Therefore, the second purge gas distribution unit may implement a purge function, and moreover, may divide a space between the substrate supporting unit 3 and the chamber lid 4 into a plurality of areas along the first rotational direction (the R1 arrow direction). The second purge gas distribution unit may be installed in the chamber lid 4 so as to be located over the substrate supporting unit 3.

The second purge gas distribution unit may be installed in the chamber lid 4 at a position spaced apart from the reactant gas distribution unit 5a along the first rotational direction (the R1 arrow direction). Therefore, the second purge gas distribution unit may implement an air curtain between the source gas distribution area 50b and the reactant gas distribution area 50a, thereby spatially dividing the source gas distribution area 50b and the reactant gas distribution area 50a. Also, the second purge gas distribution unit may distribute the purge gas to the substrate S which has undergone the reactant gas distribution area 50a, thereby purging the reactant gas which remains without being deposited on the substrate S. The second purge gas distribution unit may distribute an inert gas toward the substrate supporting unit 3 as the purge gas. For example, the second purge gas distribution unit may distribute argon toward the substrate supporting unit 3 as the purge gas.

The second purge gas distribution unit and the first purge gas distribution unit may be implemented to be connected to each other. In this case, the second purge gas distribution unit and the first purge gas distribution unit may divide and distribute the purge gas supplied from one purge gas supply source. The second purge gas distribution unit and the first purge gas distribution unit may be provided as one body.

The reactant gas distribution unit 5a may be installed in plurality between the first purge gas distribution unit and the second purge gas distribution unit. The reactant gas distribution units 5a may be installed in the chamber lid 4 at positions spaced apart from each other along the first rotational direction (the R1 arrow direction). A plurality of first purge gas distribution units may be spaced apart from each other and installed in the chamber lid 4 along the first rotational direction (the R1 arrow direction) so that the first purge gas distribution unit is provided in plurality between the source gas distribution unit 5b and the reactant gas distribution unit 5a. Although not shown, a plurality of second purge gas distribution units may be spaced apart from each other and installed in the chamber lid 4 along the first rotational direction (the R1 arrow direction) so that the second purge gas distribution unit is provided in plurality between the reactant gas distribution unit 5a and the source gas distribution unit 5b.

The present inventive concept described above are not limited to the above-described embodiments and the accompanying drawings and those skilled in the art will clearly appreciate that various modifications, deformations, and substitutions are possible without departing from the scope and spirit of the invention.

1. A substrate processing apparatus comprising:
a process chamber;
a substrate supporting unit installed in the process chamber to support a plurality of substrates, the substrate supporting unit rotating about a rotational shaft;
a chamber lid covering an upper portion of the process chamber;
a plasma generator generating plasma toward the substrate supporting unit; and
a plasma shield shielding the plasma, generated by the plasma generator, in at least one of a top of the substrate and a bottom of the substrate.

2. The substrate processing apparatus of claim 1, comprising a ground body installed in the chamber lid,
wherein the plasma shield is located between the ground body and the plasma generator.

3. The substrate processing apparatus of claim 1, wherein the plasma generator comprises a first electrode, to which a plasma power is applied, and a second electrode for grounding.

4. The substrate processing apparatus of claim 3, wherein the second electrode and the plasma shield are formed of different materials.

5. The substrate processing apparatus of claim 3, wherein
the second electrode is formed of a conductor, and
the plasma shield is formed of a nonconductor or an insulator.

6. The substrate processing apparatus of claim 3, wherein
the second electrode is formed of a conductor, and
the plasma shield is formed of ceramic.

7. The substrate processing apparatus of claim 3, wherein
the plasma shield comprises a first shielding member, located between the rotational shaft of the substrate supporting unit and the first electrode to be located on the top of the substrate, and a first coupling member coupling the first shielding member to the second electrode, and
the first coupling member and the first shielding member are formed of the same material.

8. The substrate processing apparatus of claim 3, wherein the plasma shield comprises a first shielding member, located between the rotational shaft of the substrate supporting unit and the first electrode to be located on the top of the substrate, and the first shielding member is coupled to the second electrode to contact the first electrode.

9. The substrate processing apparatus of claim 3, wherein
the plasma shield comprises a first shielding member, located between the rotational shaft of the substrate supporting unit and the first electrode to be located on the top of the substrate, and a second shielding member located at a position spaced apart from the first shielding member to be located on the bottom of the substrate, and
the first electrode is located between the first shielding member and the second shielding member, and the second electrode is located between the first shielding member and the second shielding member.

10. The substrate processing apparatus of claim 9, wherein
the plasma shield comprises a second coupling member coupling the second shielding member to the second electrode, and
the second coupling member and the second shielding member are formed of the same material.

11. The substrate processing apparatus of claim 1, comprising a source gas distribution unit installed in the chamber lid to distribute a source gas toward the substrate supporting unit, a reactant gas distribution unit installed in the chamber lid to distribute a reactant gas toward the substrate supporting unit, a first purge gas distribution unit installed in the chamber lid at a position spaced apart from the source gas distribution unit along a rotational direction of the substrate supporting unit, and a second purge gas distribution unit installed in the chamber lid at a position spaced apart from the reactant gas distribution unit along the rotational direction of the substrate supporting unit,
wherein
the reactant gas distribution unit is installed in the chamber lid at a position spaced apart from the first purge gas distribution unit along the rotational direction of the substrate supporting unit, and
the source gas distribution unit is installed in the chamber lid at a position spaced apart from the second purge gas distribution unit along the rotational direction of the substrate supporting unit.

12. The substrate processing apparatus of claim 11, wherein the reactant gas distribution unit is installed in plurality between the first purge gas distribution unit and the second purge gas distribution unit, and the reactant gas distribution units are installed in the chamber lid at positions spaced apart from each other along the rotational direction of the substrate supporting unit.

13. A gas distribution apparatus for substrate processing apparatuses, the gas distribution apparatus comprising:
a plasma generator generating plasma for performing a processing process on a substrate supported by a substrate supporting unit;
a ground body coupled to the plasma generator; and
a plasma shield shielding the plasma generated by the plasma generator,
wherein the plasma generator comprises a first electrode for generating the plasma and a second electrode coupled to the ground body at a position spaced apart from the first electrode so that a gas distribution space for distributing a process gas is provided between the first electrode and the second electrode, and the plasma shield shields the plasma, generated by the plasma generator, in at least one of a top of the substrate and a bottom of the substrate.

14. The gas distribution apparatus of claim 13, wherein
the second electrode is formed of a conductor, and
the plasma shield is formed of a nonconductor or an insulator.

15. The gas distribution apparatus of claim 13, wherein
the second electrode is formed of a conductor, and
the plasma shield is formed of ceramic.

16. The gas distribution apparatus of claim 13, wherein
the plasma shield comprises a first shielding member, located between a rotational shaft of the substrate supporting unit and the first electrode to be located on the top of the substrate, and a first coupling member coupling the first shielding member to the second electrode, and
the first coupling member and the first shielding member are formed of the same material.

17. The gas distribution apparatus of claim 13, wherein the plasma shield is coupled to the second electrode to contact the first electrode.

18. The gas distribution apparatus of claim 13, wherein
the plasma shield comprises a first shielding member, located between a rotational shaft of the substrate supporting unit and the first electrode to be located on the top of the substrate, and a second shielding member located at a position spaced apart from the first shielding member to be located on the bottom of the substrate,
the first electrode is located between the first shielding member and the second shielding member,
the second electrode is located between the first shielding member and the second shielding member, and
the second shielding member is formed of a material different from a material of the second electrode.

19. The gas distribution apparatus of claim 18, wherein the second shielding member is formed of a nonconductor or an insulator and is formed of the same material as a material of the first shielding member.

20. The gas distribution apparatus of claim 18, wherein
the plasma shield comprises a second coupling member coupling the second shielding member to the second electrode, and
the second coupling member and the second shielding member are formed of the same material.
